(19) United States
(12) Patent Application Publication
(10) Pub. No.: US 2020/0021768 A1
(43) Pub. Date: Jan. 16, 2020

(54) IMAGE SENSOR AND PIXEL ARRAY CIRCUIT THEREOF

(71) Applicant: Guangzhou Tyrafos Semiconductor Technologies Co., LTD, Guangzhou (CN)

(72) Inventors: Dong-Long Lin, Taoyuan City (TW); Jia-Shyang Wang, Miaoli County (TW); Ping-Hung Yin, Taipei City (TW)

(73) Assignee: Guangzhou Tyrafos Semiconductor Technologies Co., LTD, Guangzhou (CN)

(21) Appl. No.: 16/402,254

(22) Filed: May 3, 2019

Related U.S. Application Data
(60) Provisional application No. 62/696,322, filed on Jul. 10, 2018.

(51) Int. Cl. H04N 5/3745; H04N 5/378; H04N 5/353

(52) U.S. Cl. CPC H04N 5/37452; H04N 5/353; H04N 5/378

(57) ABSTRACT

An image sensor and a pixel array circuit thereof are provided. The image sensor includes the pixel array circuit and a readout circuit. The pixel array circuit includes pixel units. Each pixel unit includes a photo sensor, N storages, N transmission circuits, and M floating diffusion nodes. The N storages are coupled to the photo sensor and configured to store charges accumulated by the photo sensor at different exposures. Each transmission circuit is coupled between a corresponding storage and a corresponding floating diffusion node, and controlled by one of N transmission control signals to transmit the charges of the corresponding storage to the corresponding floating diffusion node during a certain time period. The readout circuit is coupled to the M floating diffusion nodes and configured to obtain N digital pixel values respectively corresponding to N image frames according to voltages of the M floating diffusion nodes of each pixel unit.

### CROSS-REFERENCE TO RELATED APPLICATION

This application claims the priority benefit of U.S. provisional application Ser. No. 62/696,322, filed on Jul. 10, 2018. The entirety of the above-mentioned patent application is hereby incorporated by reference herein and made a part of this specification.

### BACKGROUND

### Technical Field

The invention relates to an image sensor, and particularly relates to an image sensor with low cost and a pixel array circuit thereof.

### Description of Related Art

In an electronic system that takes an image sensor as a slave device, the image sensor usually has a built-in storage circuit for storing digital pixel values obtained by the image sensor after an exposure operation. Besides, the storage circuit may provide the digital pixel value of a corresponding pixel in response to a reading demand of a master device in the electronic system for a subsequent image processing or image recognition operation of the master device. Therefore, the storage circuit may serve as a buffer circuit between the image sensor and the master device, so as to improve an overall speed and performance of the image sensor, and meanwhile avoid a problem of frame loss.

Generally, the storage circuit is implemented by a digital memory circuit independent to a pixel array of the image sensor, where the digital memory circuit is, for example, a Random-Access Memory (RAM), a latch or a register. However, in order to improve the overall performance of the image sensor, a memory capacity required by the storage circuit is very large, for example, a memory capacity capable of storing two image frames. In this way, a circuit area of the storage circuit of the image sensor is greatly increased, which results in increase of hardware cost of the image sensor.

### SUMMARY

The invention is directed to an image sensor and a pixel array circuit thereof, which are adapted to effectively reduce a circuit area of the image sensor, so as to reduce the cost of the image sensor.

The invention provides an image sensor including a pixel array circuit and a readout circuit. The pixel array circuit includes a plurality of pixel units. Each of the pixel units includes a photo sensor, N storages, N transmission circuits, and M floating diffusion nodes, where N is a positive integer greater than or equal to two, and M is a positive integer less than or equal to N. The photo sensor is coupled to a first node. The N storages are coupled to the first node and respectively configured to store charges accumulated by the photo sensor at different exposures. Each of the N transmission circuits is coupled between one of the N storages and one of the M floating diffusion nodes, and is controlled by one of N transmission control signals to transmit the charges stored in the corresponding one of the N storages to the corresponding one of the M floating diffusion nodes during a specific time period. The readout circuit is coupled to the M floating diffusion nodes of each of the pixel units, and is configured to obtain N digital pixel values respectively corresponding to N image frames according to voltages of the M floating diffusion nodes of each of the pixel units.

In an embodiment of the invention, each of the N storages is an analog memory cell.

In an embodiment of the invention, each of the N storages includes a storage switch and a charge storage element. A first terminal of the storage switch is coupled to the first node. A control terminal of the storage switch receives one of N storage control signals. A second terminal of the storage switch is coupled to one of the N transmission circuits. The charge storage element is coupled to the second terminal of the storage switch, and configured to storage the charges from the photo sensor.

In an embodiment of the invention, each of the N transmission circuits includes a transmission switch and a reset switch. A first terminal of the transmission switch is coupled to one of the N storages. A second terminal of the transmission switch is coupled to one of the M floating diffusion nodes. A control terminal of the transmission switch receives one of the N transmission control signals. A first terminal of the reset switch is coupled to a reset power. A second terminal of the reset switch is coupled to the corresponding one of the M floating diffusion nodes. A control terminal of the reset switch receives one of N reset control signals, where M is equal to N.

In an embodiment of the invention, each of the N transmission circuits includes a transmission switch. A first terminal of the transmission switch is coupled to one of the N storages. A second terminal of the transmission switch is coupled to the M floating diffusion nodes. A control terminal of the transmission switch receives one of the N transmission control signals. Each of the pixel units further includes a reset switch. A first terminal of the reset switch is coupled to a reset power. A second terminal of the reset switch is coupled to the M floating diffusion nodes. A control terminal of the reset switch receives a reset control signal, where M is equal to one.

In an embodiment of the invention, when the pixel array circuit performs the exposure operation, the photo sensors of the pixel units are simultaneously exposed.

The invention provides a pixel array circuit including a plurality of pixel units. Each of the pixel units includes a photo sensor, N storages, N transmission circuits, and M floating diffusion nodes, where N is a positive integer greater than or equal to two, and M is a positive integer less than or equal to N. The photo sensor is coupled to a first node. The N storages are coupled to the first node and respectively configured to store charges accumulated by the photo sensor at different exposures. Each of the N transmission circuits is coupled between one of the N storages and one of the M floating diffusion nodes, and is controlled by one of N transmission control signals to transmit the charges stored in the corresponding one of the N storages to the corresponding one of the M floating diffusion nodes during a specific time period.

Based on the above description, in the image sensor and the pixel array circuit provided by the embodiments of the invention, the storages are configured in each of the pixel units to store the charges accumulated by the photo sensor at different exposures. Since a circuit area of the storages used for storing the charges is smaller than the circuit area of the digital memory used for storing the digital pixel values, the hardware cost of the image sensor may be effectively reduced.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit block schematic diagram of an image sensor according to an embodiment of the invention.

FIG. 2 is a circuit block schematic diagram of a pixel unit according to an embodiment of the invention.

FIG. 3 is a circuit structural schematic diagram of the pixel unit of FIG. 2 according to an embodiment of the invention.

FIG. 4 is a timing diagram of control signals of a pixel unit according to an embodiment of the invention.

FIG. 5 is a circuit structural schematic diagram of a pixel unit according to another embodiment of the invention.

FIG. 6 is a timing diagram of control signals of the pixel unit according to another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

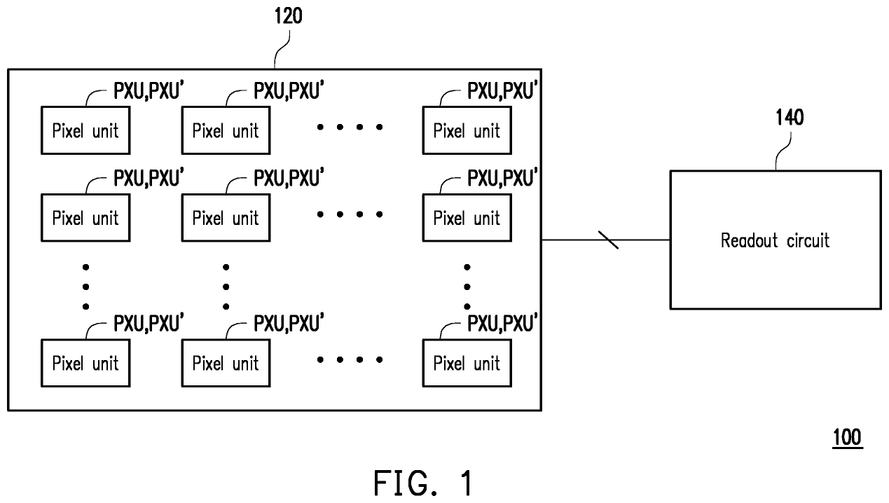

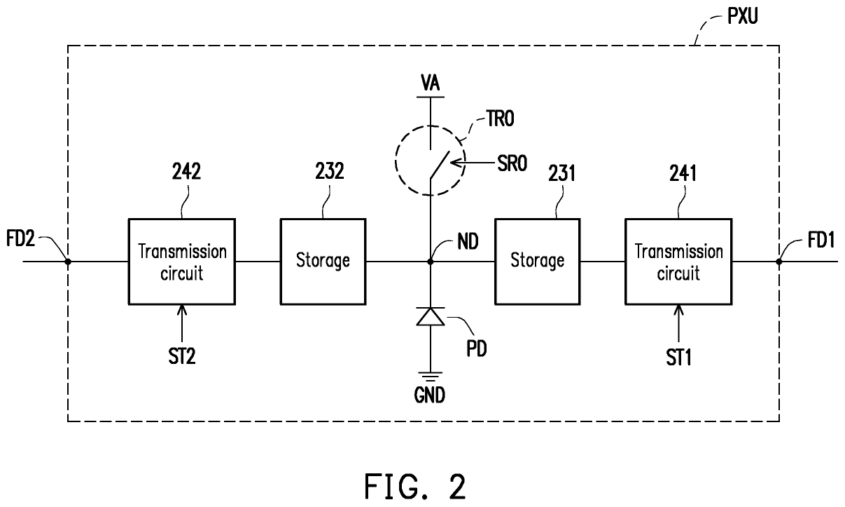

FIG. 1 is a circuit block schematic diagram of an image sensor according to an embodiment of the invention, FIG. 2 is a circuit block schematic diagram of a pixel unit according to an embodiment of the invention. Referring to FIG. 1 and FIG. 2, the image sensor 100 may include a pixel array circuit 120 and a readout circuit 140. The pixel array circuit 120 may include a plurality of pixel units PXU arranged in an array. Each of the pixel units PXU may include a photo sensor PD, N storages, N transmission circuits, and M floating diffusion nodes, where N is a positive integer greater than or equal to two, and M is a positive integer less than or equal to N. However, for simplicity's sake, an exemplary embodiment where N is two is described below, and implementations where N is greater than two may be deduced by anology according to following descriptions. Moreover, FIG. 2 is an exemplary embodiment where M is two, and implementation where M is one is described in detail later.

As shown in FIG. 2, each of the pixel units PXU includes a photo sensor PD, two storages 231 and 232, two transmission circuits 241 and 242 and two floating diffusion nodes FD1 and FD2. An anode of the photo sensor PD is coupled to a ground terminal GND. A cathode of the photo sensor PD is coupled to a first node ND. Particularly, when the pixel array circuit 120 performs an exposure operation, the photo sensors PD of the pixel units PXU are simultaneously exposed, so as to implement a global shutter exposure operation.

The storages 231 and 232 are coupled to the first node ND. The storages 231 and 232 may respectively store charges accumulated by the photo sensor PD at different exposures. For example, the storage 231 may store charges accumulated by the photo sensor PD at an L^{th} exposure, and the storage 232 may store charges accumulated by the photo sensor PD at an (L+1)^{th} exposure, where L is a positive integer. It should be noted that the charges stored by the storages 231 of all of the pixel units PXU of the pixel array circuit 120 correspond to one image frame, and the charges stored by the storages 232 of all of the pixel units PXU of the pixel array circuit 120 correspond to another image frame. In other words, through the circuit design that each of the pixel units PXU has two storages 231 and 232, the pixel array circuit 120 may have a memory capacity of two image frames.

The transmission circuit 241 is coupled between the storage 231 and the floating diffusion node FD1, and is controlled by a transmission control signal ST1 to transmit the charges stored in the storage 231 to the floating diffusion node FD1 during one specific time period. Similarly, the transmission circuit 242 is coupled between the storage 232 and the floating diffusion node FD2, and is controlled by a transmission control signal ST2 to transmit the charges stored in the storage 232 to the floating diffusion node FD2 during another specific time period.

The readout circuit 140 is coupled to the floating diffusion nodes FD1 and FD2 of each of the pixel units PXU. The readout circuit 140 may obtain digital pixel values corresponding to one image frame according to voltages of the floating diffusion nodes FD1 of the pixel units PXU. Similarly, the readout circuit 140 may obtain digital pixel values corresponding to another image frame according to voltages of the floating diffusion nodes FD2 of the pixel units PXU.

It should be noted that since the storages 231 and 232 are used for storing charges, compared to a general digital memory circuit used for storing the digital pixel values, a circuit area of the storages 231 and 232 is smaller, so that the hardware cost of the image sensor 100 may be effectively reduced.

In an embodiment of the invention, the storages 231 and 232 may be implemented by various types of analog memory cells.

In an embodiment of the invention, each of the pixel units PXU may further include a reset switch TR0. A first terminal of the reset switch TR0 is coupled to a reset power VA. A second terminal of the reset switch TR0 is coupled to the first node ND. A control terminal of the reset switch TR0 receives a reset control signal SR0. The reset control signal SR0 may control turning on/off of the reset switch TR0, so as to control resetting of the photo sensor PD. In an embodiment of the invention, the reset switch TR0 may be implemented by a Metal-Oxide-Semiconductor Field-Effective Transistor (MOSFET), though the invention is not limited thereto.

In an embodiment of the invention, each of the pixel units PXU may further include other circuits used for cooperatively performing the readout operation, for example, two source follower transistors, which are respectively coupled to the floating diffusion nodes FD1 and FD2 to convert the charges of the floating diffusion nodes FD1 and FD2 into the corresponding voltages.

In an embodiment of the invention, the readout circuit 140 may be implemented by an existing readout circuit. For example, the readout circuit 140 may be implemented by a readout circuit having a Correlated Double Sampling (CDS) circuit and an Analog-to-Digital Converter (ADC), though the invention is not limited thereto, and the circuit structure of the readout circuit 140 is not limited by the invention. Since the implementations and operations of the readout circuit are well known by those skilled in the art, detail thereof is not repeated.

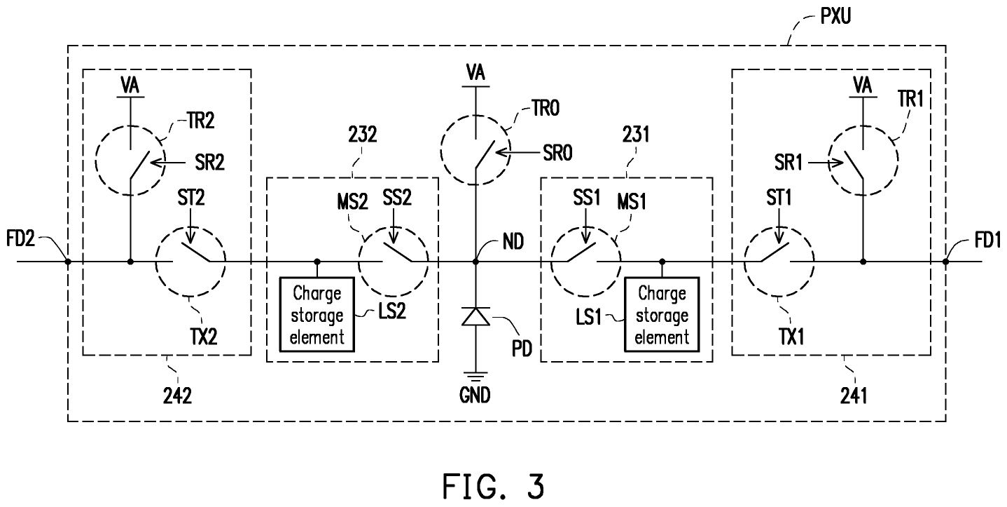

FIG. 3 is a circuit structural schematic diagram of the pixel unit of FIG. 2 according to an embodiment of the invention. Referring to FIG. 3, the storage 231 may include a storage switch MS1 and a charge storage element LS1. A first terminal of the storage switch MS1 is coupled to the first node ND. A control terminal of the storage switch MS1 receives a storage control signal SS1. A second terminal of the storage switch MS1 is coupled to the charge storage element LS1, and coupled to the transmission circuit 241. When the storage switch MS1 is turned on, the charge storage element LS1 may store the charges coming from the photo sensor PD.

Similarly, the storage 232 may include a storage switch MS2 and a charge storage element LS2. A first terminal of the storage switch MS2 is coupled to the first node ND. A control terminal of the storage switch MS2 receives a storage control signal SS2. A second terminal of the storage switch MS2 is coupled to the charge storage element LS2, and coupled to the transmission circuit 242. When the storage switch MS2 is turned on, the charge storage element LS2 may store the charges coming from the photo sensor PD.

The transmission circuit 241 may include a transmission switch TX1 and a reset switch TR1. A first terminal of the transmission switch TX1 is coupled to the storage 231. A second terminal of the transmission switch TX1 is coupled to the floating diffusion node FD1. A control terminal of the transmission switch TX1 receives the transmission control signal ST1. A first terminal of the reset switch TR1 is coupled to the reset power VA. A second terminal of the reset switch TR1 is coupled to the floating diffusion node FD1. A control terminal of the reset switch TR1 receives a reset control signal SR1.

Similarly, the transmission circuit 242 may include a transmission switch TX2 and a reset switch TR2. A first terminal of the transmission switch TX2 is coupled to the storage 232. A second terminal of the transmission switch TX2 is coupled to the floating diffusion node FD2. A control terminal of the transmission switch TX2 receives the transmission control signal ST2. A first terminal of the reset switch TR2 is coupled to the reset power VA. A second terminal of the reset switch TR2 is coupled to the floating diffusion node FD2. A control terminal of the reset switch TR2 receives a reset control signal SR2.

In an embodiment of the invention, the charge storage elements LS1 and LS2 may be implemented by capacitors or diodes, though the invention is not limited thereto.

In an embodiment of the invention, the storage switches MS1 and MS2, the reset switches TR1 and TR2 and the transmission switches TX1 and TX2 may be implemented by MOSFETs, though the invention is not limited thereto.

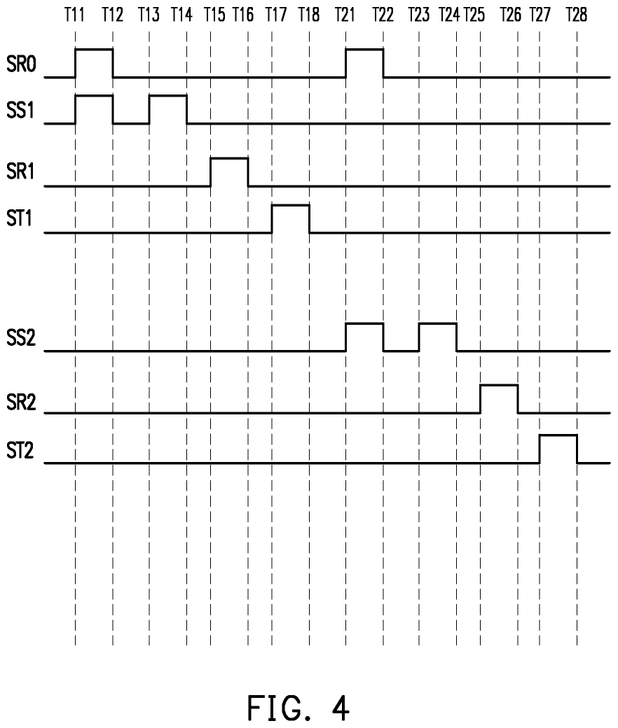

FIG. 4 is a timing diagram of the control signals of the pixel unit according to an embodiment of the invention. An exposure and storage operation of the image sensor 100 of FIG. 1 is described below with reference of the pixel unit PXU of FIG. 3 and the control signal timing diagram of FIG. 4. Referring to FIG. 1, FIG. 3 and FIG. 4, in FIG. 3, a first exposure and storage operation may be performed by the photo sensor PD and the storage 231. First, at a time point T11, the reset control signal SR0 and the storage control signal SS1 may be driven to a first level (for example, a logic high level) to turn on the reset switches TR0 and the storage switches MS1 of all of the pixel units PXU, so as to reset the photo sensors PD and the charge storage elements LS1 of all of the pixel units PXU. Then, at a time point T12, the reset control signal SR0 and the storage control signal SS1 may be driven to a second level (for example, a logic low level) to turn off the reset switches TR0 and the storage switches MS1 of all of the pixel units PXU, and the photo sensors PD of all of the pixel units PXU are simultaneously exposed to light for a period of exposure time for integration. After the exposure of the photo sensors PD of all of the pixel units PXU is completed, at a time point T13, the storage control signal SS1 may be driven to the first level to turn on the storage switch MS1, so as to transmit the charges of the photo sensor PD to the charge storage element LS1. Then, at a time point T14, the storage control signal SS1 may be driven to the second level to turn off the storage switch MS1, so as to complete the storage operation corresponding to the first exposure.

After the first exposure and storage operation is completed, a readout operation corresponding to the first exposure and storage operation may be performed by the transmission circuit 241 and the readout circuit 140. First, at a time point T15, the reset control signal SR1 may be driven to the first level to turn on the reset switch TR1, so as to reset the floating diffusion node FD1, such that a voltage of the floating diffusion node FD1 is equal to the voltage of the reset power VA. Then, at a time point T16, the reset control signal SR1 may be driven to the second level to turn off the reset switch TR1. Thereafter, within the specific time period between time points T17-T18, the transmission control signal ST1 is driven to the first level to turn on the transmission switch TX1, so as to transmit the charges stored in the charge storage element LS1 to the floating diffusion node FD1. In this way, the readout circuit 140 may obtain the digital pixel values corresponding to a first image frame according to the voltages of the floating diffusion nodes FD1 of the pixel units PXU.

Moreover, a second exposure and storage operation may be performed by the photo sensor PD and the storage 232. First, at a time point T21, the reset control signal SR0 and the storage control signal SS2 may be driven to the first level to turn on the reset switches TR0 and the storage switches MS2 of all of the pixel units PXU, so as to reset the photo sensors PD and the charge storage elements LS2 of all of the pixel units PXU. Then, at a time point T22, the reset control signal SR0 and the storage control signal SS2 may be driven to the second level to turn off the reset switches TR0 and the storage switches MS2 of all of the pixel units PXU, and the photo sensors PD of all of the pixel units PXU are simultaneously exposed to light for a period of exposure time for integration. After the exposure of the photo sensors PD of all of the pixel units PXU is completed, at a time point T23, the storage control signal SS2 may be driven to the first level to turn on the storage switch MS2, so as to transmit the charges of the photo sensor PD to the charge storage element LS2. Then, at a time point T24, the storage control signal SS2 may be driven to the second level to turn off the storage switch MS2, so as to complete the storage operation corresponding to the second exposure.

After the second exposure and storage operation is completed, a readout operation corresponding to the second exposure and storage operation may be performed by the transmission circuit 242 and the readout circuit 140. First, at a time point T25, the reset control signal SR2 may be driven to the first level to turn on the reset switch TR2, so as to reset the floating diffusion node FD2, such that a voltage of the floating diffusion node FD2 is equal to the voltage of the reset power VA. Then, at a time point T26, the reset control signal SR2 may be driven to the second level to turn off the reset switch TR2. Thereafter, within the specific time period between time points T27-T28, the transmission control signal ST2 is driven to the first level to turn on the transmission switch TX2, so as to transmit the charges stored in the charge storage element LS2 to the floating diffusion node FD2. In this way, the readout circuit 140 may obtain the digital pixel values corresponding to a second image frame according to the voltages of the floating diffusion nodes FD2 of the pixel units PXU.

In an embodiment of the invention, in order to accelerate an operation speed and improve efficiency of the image sensor 100, the operations of the photo sensor PD and the storage 232 and the operations of the transmission circuit 241 and the readout circuit 140 may be pipelined, and the operations of the photo sensor PD and the storage 231 and the operations of the transmission circuit 242 and the readout circuit 140 may be pipelined. In detail, when the transmission circuit 241 and the readout circuit 140 perform the readout operation corresponding to a K^{th} exposure and storage operation, the photo sensor PD and the storage 232 may perform a (K+1)^{th} exposure and storage operation, where K is a positive integer. When the transmission circuit 242 and the readout circuit 140 perform the readout operation corresponding to the (K+1)^{th} exposure and storage operation, the photo sensor PD and the storage 231 may perform a (K+2)^{th} exposure and storage operation.

For example, when the transmission circuit 241 and the readout circuit 140 perform the readout operation corresponding to the first exposure and storage operation, the photo sensor PD and the storage 232 may perform the second exposure and storage operation. When the transmission circuit 242 and the readout circuit 140 perform the readout operation corresponding to the second exposure and storage operation, the photo sensor PD and the storage 231 may perform a third exposure and storage operation.

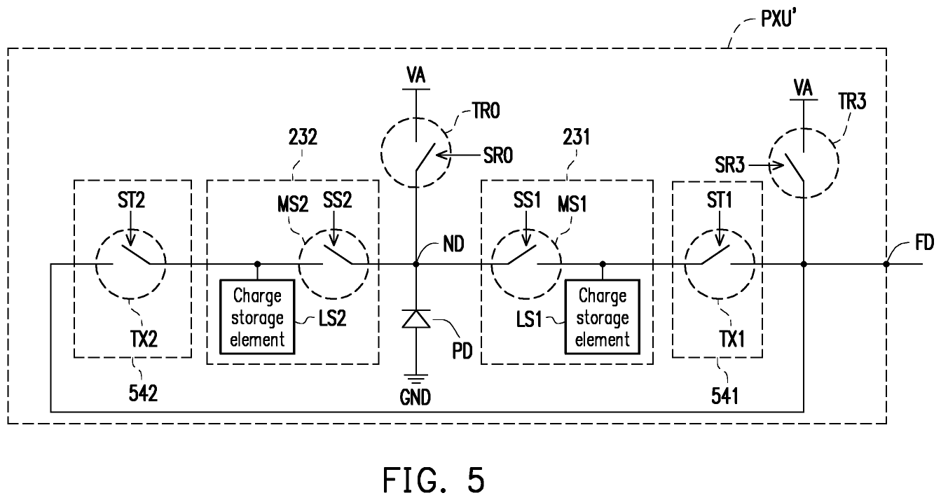

FIG. 5 is a circuit structural schematic diagram of a pixel unit according to another embodiment of the invention. Referring to FIG. 1 and FIG. 5, each of the pixel units PXU′ includes reset switches TR0 and TR3, a photo sensor PD, two storages 231 and 232, two transmission circuits 541 and 542 and one floating diffusion node FD, where implementations of the reset switch TR0, the photo sensor PD and the storages 231 and 232 of FIG. 5 are respectively similar to that of the reset switch TR0, the photo sensor PD and the storages 231 and 232 of FIG. 2 (or FIG. 3), so that related descriptions of FIG. 2-FIG. 3 may be referred, and details thereof are not repeated.

The transmission circuit 541 is coupled between the storage 231 and the floating diffusion node FD, and is controlled by the transmission control signal ST1 to transmit the charges stored in the storage 231 to the floating diffusion node FD during one specific time period. Similarly, the transmission circuit 542 is coupled between the storage 232 and the floating diffusion node FD, and is controlled by the transmission control signal ST2 to transmit the charges stored in the storage 232 to the floating diffusion node FD during another specific time period.

The transmission circuit 541 may include a transmission switch TX1. A first terminal of the transmission switch TX1 is coupled to the storage 231. A second terminal of the transmission switch TX1 is coupled to the floating diffusion node FD. A control terminal of the transmission switch TX1 receives the transmission control signal ST1. Similarly, the transmission circuit 542 may include a transmission switch TX2. A first terminal of the transmission switch TX2 is coupled to the storage 232. A second terminal of the transmission switch TX2 is coupled to the floating diffusion node FD. A control terminal of the transmission switch TX2 receives the transmission control signal ST2.

A first terminal of the reset switch TR3 is coupled to the reset power VA. A second terminal of the reset switch TR3 is coupled to the floating diffusion node FD. A control terminal of the reset switch TR3 receives a reset control signal SR3. The reset control signal SR3 may control turning on/off of the reset switch TR3, so as to control resetting of the floating diffusion node FD. In an embodiment of the invention, the reset switch TR3 may be implemented by a MOSFET, though the invention is not limited thereto.

The readout circuit 140 is coupled to the floating diffusion node FD of each of the pixel units PXU′. The readout circuit 140 may sequentially obtain the digital pixel values corresponding to two image frames according to the voltages of the floating diffusion nodes FD of the pixel units PXU′.

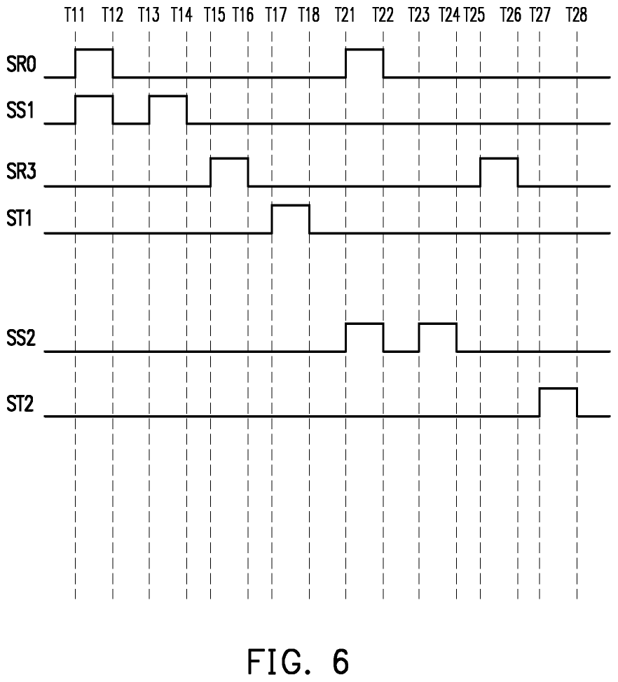

FIG. 6 is a timing diagram of the control signals of the pixel unit according to another embodiment of the invention. An exposure and storage operation of the image sensor 100 of FIG. 1 is described below with reference of the pixel unit PXU′ of FIG. 5 and the control signal timing diagram of FIG. 6. Referring to FIG. 1, FIG. 5 and FIG. 6, in FIG. 5, a first exposure and storage operation may be performed by the photo sensor PD and the storage 231. First, at a time point T11, the reset control signal SR0 and the storage control signal SS1 may be driven to a first level (for example, a logic high level) to turn on the reset switches TR0 and the storage switches MS1 of all of the pixel units PXU′, so as to reset the photo sensors PD and the charge storage elements LS1 of all of the pixel units PXU′. Then, at a time point T12, the reset control signal SR0 and the storage control signal SS1 may be driven to a second level (for example, a logic low level) to turn off the reset switches TR0 and the storage switches MS1 of all of the pixel units PXU′, and the photo sensors PD of all of the pixel units PXU′ are simultaneously exposed to light for a period of exposure time for integration. After the exposure of the photo sensors PD of all of the pixel units PXU′ is completed, at a time point T13, the storage control signal SS1 may be driven to the first level to turn on the storage switch MS1, so as to transmit the charges of the photo sensor PD to the charge storage element LS1. Then, at a time point T14, the storage control signal SS1 may be driven to the second level to turn off the storage switch MS1, so as to complete the storage operation corresponding to the first exposure.

After the first exposure and storage operation is completed, a readout operation corresponding to the first exposure and storage operation may be performed by the transmission circuit 541, the reset switch TR3 and the readout circuit 140. First, at a time point T15, the reset control signal SR3 may be driven to the first level to turn on the reset switch TR3, so as to reset the floating diffusion node FD, such that a voltage of the floating diffusion node FD is equal to the voltage of the reset power VA. Then, at a time point T16, the reset control signal SR3 may be driven to the second level to turn off the reset switch TR3. Thereafter, within the specific time period between time points T17-T18, the transmission control signal ST1 is driven to the first level to turn on the transmission switch TX1, so as to transmit the charges stored in the charge storage element LS1 to the floating diffusion node FD. In this way, the readout circuit 140 may obtain the digital pixel values corresponding to a first image frame according to the voltages of the floating diffusion nodes FD of the pixel units PXU′.

Moreover, a second exposure and storage operation may be performed by the photo sensor PD and the storage 232. First, at a time point T21, the reset control signal SR0 and the storage control signal SS2 may be driven to the first level to turn on the reset switches TR0 and the storage switches MS2 of all of the pixel units PXU′, so as to reset the photo sensors PD and the charge storage elements LS2 of all of the pixel units PXU′. Then, at a time point T22, the reset control signal SR0 and the storage control signal SS2 may be driven to the second level to turn off the reset switches TR0 and the storage switches MS2 of all of the pixel units PXU′, and the photo sensors PD of all of the pixel units PXU′ are simultaneously exposed to light for a period of exposure time for integration. After the exposure of the photo sensors PD of all of the pixel units PXU′ is completed, at a time point T23, the storage control signal SS2 may be driven to the first level to turn on the storage switch MS2, so as to transmit the charges of the photo sensor PD to the charge storage element LS2. Then, at a time point T24, the storage control signal SS2 may be driven to the second level to turn off the storage switch MS2, so as to complete the storage operation corresponding to the second exposure.

After the second exposure and storage operation is completed, a readout operation corresponding to the second exposure and storage operation may be performed by the transmission circuit 542, the reset switch TR3 and the readout circuit 140. First, at a time point T25, the reset control signal SR3 may be driven to the first level to turn on the reset switch TR3, so as to reset the floating diffusion node FD, such that a voltage of the floating diffusion node FD is equal to the voltage of the reset power VA. Then, at a time point T26, the reset control signal SR3 may be driven to the second level to turn off the reset switch TR3. Thereafter, within the specific time period between time points T27-T28, the transmission control signal ST2 is driven to the first level to turn on the transmission switch TX2, so as to transmit the charges stored in the charge storage element LS2 to the floating diffusion node FD. In this way, the readout circuit 140 may obtain the digital pixel values corresponding to a second image frame according to the voltages of the floating diffusion nodes FD of the pixel units PXU′.

It should be noted that since the storage 231 and the storage 232 share the same floating diffusion mode FD, only one reset switch TR3 is required to be disposed at the floating diffusion mode FD of each of the pixel units PXU′. In this way, the circuit area of each of the pixel units PXU′ may be reduced.

In an embodiment of the invention, in order to accelerate an operation speed and improve efficiency of the image sensor 100, the operations of the photo sensor PD and the storage 232 and the operations of the transmission circuit 541, the reset switch TR3 and the readout circuit 140 may be pipelined, and the operations of the photo sensor PD and the storage 231 and the operations of the transmission circuit 542, the reset switch TR3 and the readout circuit 140 may be pipelined. In detail, when the transmission circuit 541, the reset switch TR3 and the readout circuit 140 perform the readout operation corresponding to a K^{th} exposure and storage operation, the photo sensor PD and the storage 232 may perform a (K+1)^{th} exposure and storage operation, where K is a positive integer. When the transmission circuit 542, the reset switch TR3 and the readout circuit 140 perform the readout operation corresponding to the (K+1)^{th} exposure and storage operation, the photo sensor PD and the storage 231 may perform a (K+2)^{th} exposure and storage operation.

For example, when the transmission circuit 541, the reset switch TR3 and the readout circuit 140 perform the readout operation corresponding to the first exposure and storage operation, the photo sensor PD and the storage 232 may perform the second exposure and storage operation. When the transmission circuit 542, the reset switch TR3 and the readout circuit 140 perform the readout operation corresponding to the second exposure and storage operation, the photo sensor PD and the storage 231 may perform a third exposure and storage operation.

In summary, in the image sensor and the pixel array circuit provided by the embodiments of the invention, the storages are configured in each of the pixel units to store the charges accumulated by the photo sensor at different exposures. Since a circuit area of the storages used for storing the charges is smaller than the circuit area of the digital memory used for storing the digital pixel values, the hardware cost of the image sensor may be effectively reduced. Moreover, a plurality of storages are configured in each of the pixel units to respectively store the charges accumulated by the photo sensor at different exposures, and the global shutter exposure operation is adopted, the pixel array circuit may have a memory capacity of multiple image frames.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

What is claimed is:

1. An image sensor, comprising:
a pixel array circuit, comprising a plurality of pixel units, wherein each of the pixel units comprises:
M floating diffusion nodes;
a photo sensor, coupled to a first node;
N storages, coupled to the first node, and respectively configured to store charges accumulated by the photo sensor at different exposures, wherein N is a positive integer greater than or equal to two, and M is a positive integer less than or equal to N; and
N transmission circuits, wherein each of the N transmission circuits is coupled between one of the N storages and one of the M floating diffusion nodes, and is controlled by one of N transmission control signals to transmit the charges stored in the corresponding one of the N storages to the corresponding one of the M floating diffusion nodes during a specific time period; and
a readout circuit, coupled to the M floating diffusion nodes of each of the pixel units, and configured to obtain N digital pixel values respectively corresponding to N image frames according to voltages of the M floating diffusion nodes of each of the pixel units.

2. The image sensor as claimed in claim 1, wherein each of the N storages is an analog memory cell.

3. The image sensor as claimed in claim 1, wherein each of the N storages comprises:
a storage switch, having a first terminal coupled to the first node, a control terminal receiving one of N storage control signals, and a second terminal coupled to one of the N transmission circuits; and
a charge storage element, coupled to the second terminal of the storage switch, and configured to storage the charges from the photo sensor.

4. The image sensor as claimed in claim 1, wherein each of the N transmission circuits comprises:
a transmission switch, having a first terminal coupled to one of the N storages, a second terminal coupled to one of the M floating diffusion nodes, and a control terminal receiving one of the N transmission control signals; and
a reset switch, having a first terminal coupled to a reset power, a second terminal coupled to the corresponding one of the M floating diffusion nodes, and a control terminal receiving one of N reset control signals, wherein M is equal to N.

5. The image sensor as claimed in claim 1, wherein each of the N transmission circuits comprises:
a transmission switch, having a first terminal coupled to one of the N storages, a second terminal coupled to the M floating diffusion nodes, and a control terminal receiving one of the N transmission control signals,
wherein each of the pixel units further comprises:
a reset switch, having a first terminal coupled to a reset power, a second terminal coupled to the M floating diffusion nodes, and a control terminal receiving a reset control signal, wherein M is equal to one.

6. The image sensor as claimed in claim 1, wherein each of the pixel units further comprises:
a reset switch, having a first terminal coupled to a reset power, a second terminal coupled to the first node, and a control terminal receiving a reset control signal.

7. The image sensor as claimed in claim 1, wherein when the pixel array circuit performs an exposure operation, the photo sensors of the pixel units are simultaneously exposed.

8. A pixel array circuit, comprising:
a plurality of pixel units, wherein each of the pixel units comprises:
M floating diffusion nodes;
a photo sensor, coupled to a first node;
N storages, coupled to the first node, and respectively configured to store charges accumulated by the photo sensor at different exposures, wherein N is a positive integer greater than or equal to two, and M is a positive integer less than or equal to N; and
N transmission circuits, wherein each of the N transmission circuits is coupled between one of the N storages and one of the M floating diffusion nodes, and is controlled by one of N transmission control signals to transmit the charges stored in the corresponding one of the N storages to the corresponding one of the M floating diffusion nodes during a specific time period.

9. The pixel array circuit as claimed in claim 8, wherein each of the N storages is an analog memory cell.

10. The pixel array circuit as claimed in claim 8, wherein each of the N storages comprises:
a storage switch, having a first terminal coupled to the first node, a control terminal receiving one of N storage control signals, and a second terminal coupled to one of the N transmission circuits; and
a charge storage element, coupled to the second terminal of the storage switch, and configured to storage the charges from the photo sensor.

11. The pixel array circuit as claimed in claim 8, wherein each of the N transmission circuits comprises:
a transmission switch, having a first terminal coupled to one of the N storages, a second terminal coupled to one of the M floating diffusion nodes, and a control terminal receiving one of the N transmission control signals; and
a reset switch, having a first terminal coupled to a reset power, a second terminal coupled to the corresponding one of the M floating diffusion nodes, and a control terminal receiving one of N reset control signals, wherein M is equal to N.

12. The pixel array circuit as claimed in claim 8, wherein each of the N transmission circuits comprises:
a transmission switch, having a first terminal coupled to one of the N storages, a second terminal coupled to the M floating diffusion nodes, and a control terminal receiving one of the N transmission control signals,
wherein each of the pixel units further comprises:
a reset switch, having a first terminal coupled to a reset power, a second terminal coupled to the M floating diffusion nodes, and a control terminal receiving a reset control signal, wherein M is equal to one.

13. The pixel array circuit as claimed in claim 8, wherein each of the pixel units further comprises:
a reset switch, having a first terminal coupled to a reset power, a second terminal coupled to the first node, and a control terminal receiving a reset control signal.

14. The pixel array circuit as claimed in claim 8, wherein when the pixel array circuit performs an exposure operation, the photo sensors of the pixel units are simultaneously exposed.
